(19) United States
(12) Patent Application Publication
(10) Pub. No.: US 2025/0218485 A1
(43) Pub. Date: Jul. 3, 2025

(54) DEVICE, METHOD AND SYSTEM TO THROTTLE CIRCUIT OPERATIONS BASED ON A REQUESTED MEMORY REFRESH RATE

(71) Applicant: Intel Corporation, Santa Clara, CA (US)

(72) Inventors: Yevgeni Sabin, Haifa (IL); Tomer Levy, Tel Aviv (IL); Dor Zvik, Herzelia (IL); Zeev Offen, Folsom, CA (US); Mark Gallina, Hillsboro, OR (US); Dorit Shapira, Portland, OR (US); Yoni Aizik, Haifa (IL)

(73) Assignee: Intel Corporation, Santa Clara, CA (US)

(21) Appl. No.: 18/397,659

(22) Filed: Dec. 27, 2023

(51) Int. Cl. G11C 11/406; G11C 11/4078; G11C 29/02

(52) U.S. Cl. CPC G11C 11/40615; G11C 11/4078; G11C 29/028

(57) ABSTRACT

Techniques and mechanisms for selectively throttling operation of circuitry, wherein said throttling is based on a threshold rate at which a memory is to be refreshed. In an embodiment, a power management unit (PMU) accommodates coupling to receive an identifier of a first refresh rate which has been requested with the random access memory (RAM) device. The PMU provides functionality to calculate a difference between a threshold maximum refresh rate and the first refresh rate. Based on the calculated difference, a throttle action is identified, and one or more control signals are generated to throttle operation of circuitry which is thermally coupled with the RAM device. In another embodiment, the RAM device continues to be refreshed at the first refresh rate during and/or after the throttling of the circuitry.

### BACKGROUND

### 1. Technical Field

This disclosure generally relates to thermal regulation of a memory and more particularly, but not exclusively, to throttling of circuit operations based on a requested memory refresh rate.

### 2. Background Art

The temperature of a semiconductor memory, such as a RAM (random access memory) is largely determined by its activity level (rate of reads and writes into the memory cells) and its environment. If the temperature of a RAM becomes too high, then the data stored in the memory may be corrupted or lost.

In addition, as the temperature of a solid state memory increases, the memory loses charge at a faster rate. If the memory loses charge, then it loses the data that was stored in its memory cells. RAM chips often have self-refresh circuitry that restores the lost charge at periodic intervals. As the temperature increases the self-refresh rate must be increased in order to avoid losing the data. This increases power consumption.

In order to keep the refresh rates low and to avoid damage to the memory or loss of data, some information about the memory temperature must be known. The more accurate the temperature information, the hotter the memory may be permitted to run and the lower the refresh rate may be without risk of data loss. If the temperature information is not reliable or accurate, then the memory is run at a slower access rate and a faster refresh rate then necessary in order to provide some margin for error.

Memory is often packaged in modules that contain several similar or identical integrated circuit (IC) chips, such as dynamic random access memory (DRAM) chips. The temperature of each chip may be different, depending on its level of use, available cooling and its own unique characteristics. Other devices on the memory module may have different temperatures as well. In order to accurately monitor all aspects of such a memory module, thermal circuitry is often provided for each DRAM chip and maybe even for different portions of each DRAM chip. In addition, a communication system is usually used to transfer all of the temperature information to a device that can interpret the information and cause some action to be taken, if necessary.

As successive generations of processor-capable systems continue to scale in size and power consumption, there is expected to be an increasing premium placed on improvements to power management of such systems.

### BRIEF DESCRIPTION OF THE DRAWINGS

The various embodiments of the present invention are illustrated by way of example, and not by way of limitation, in the figures of the accompanying drawings and in which:

FIG. 1 shows a block diagram illustrating features of a system to selectively perform throttling based on refresh rate information according to an embodiment.

FIG. 2 shows a flow diagram illustrating features of a method to perform thermal regulation based on refresh rate information according to an embodiment.

FIG. 3 shows a block diagram illustrating features of a device to throttle operations based on refresh rate information according to an embodiment.

FIG. 4 shows a flow diagram illustrating features of a method to provide thermal regulation of a memory based on a threshold refresh rate according to an embodiment.

FIG. 5 shows a swim lane diagram illustrating operations and communications which are performed to regulate a temperature of a memory device based on a threshold refresh rate according to an embodiment.

FIG. 6 illustrates an exemplary system.

FIG. 7 illustrates a block diagram of an example processor that may have more than one core and an integrated memory controller.

FIG. 8A is a block diagram illustrating both an exemplary in-order pipeline and an exemplary register renaming, out-of-order issue/execution pipeline according to examples.

FIG. 8B is a block diagram illustrating both an exemplary example of an in-order architecture core and an exemplary register renaming, out-of-order issue/execution architecture core to be included in a processor according to examples.

### DETAILED DESCRIPTION

Embodiments discussed herein variously provide techniques and mechanisms for selectively throttling operations of circuitry based on a threshold rate at which a memory is to be refreshed. The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including logic (e.g., comprising hardware, firmware, and/or executing software) to provide power management functionality.

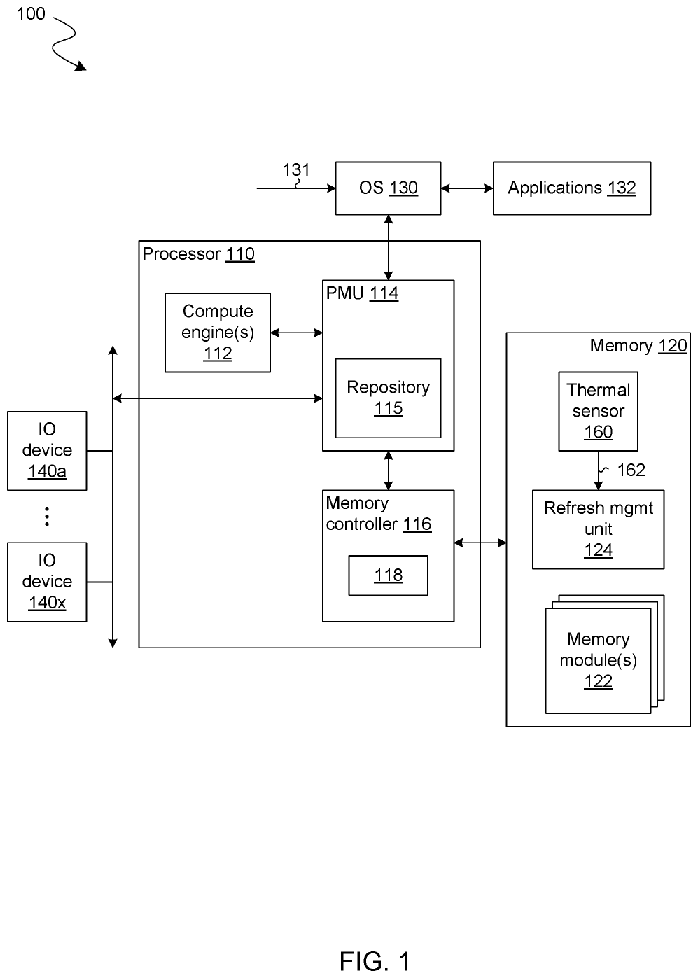

FIG. 1 shows a system 100 which selectively performs throttling based on refresh rate information according to an embodiment. System 100 illustrates features of one example embodiment wherein power management logic—e.g., comprising hardware, firmware, executing software and/or any of various suitable combinations thereof—is operable to determine whether a particular throttling action is to be initiated, continued, changed, or stopped (for example) based on a refresh rate which is requested by a memory device. In some embodiments, such power management logic performs an evaluation based on the requested refresh rate and an operational parameter which comprises an identifier of a threshold maximum refresh rate. For example, the evaluation compares the requested refresh rate to the threshold maximum refresh rate—e.g., wherein throttling is performed based on a determination that the requested refresh rate is greater than (or, for example, is sufficiently close to) the threshold maximum refresh rate.

As shown in FIG. 1, system 100 comprises processor 110, memory 120, OS 130, software applications 132, user controls 131, IO devices 140a, . . . , 140x, one or more compute engines 112 (e.g., cores), power management unit (PMU) 114, memory controller 116, and/or one or more memory modules 122. The various interfaces shown may not be actual physical in interface but conceptual data and control. In addition, there are additional data and control interfaces between various components that are used to transfer actual data but those are not shown here since they are orthogonal with respect to power, performance, and thermal management.

In some embodiments processor 110 is that of a system-on-chip (SoC) or, alternatively, is formed by one of multiple integrated circuit (IC) chips of system 100. In one such embodiment, system 100 comprises one or more packaged devices that, for example, are coupled to any of various suitable printed circuit boards. Processor 110 may include one or more compute engines 112 (e.g., cores), which may be symmetric or asymmetric. Symmetric cores are identical cores while asymmetric cores have different physical and/or functional performance. For example, asymmetric cores may include a collection of big and small cores. The one or more compute engines 112 may enter into different power states depending on their usage. Each CPU core may include its own power controller unit. In various embodiments, power management unit (PMU) 114 analyses a number of parameters to determine the power state of each compute engine 112. These parameters include workload of each compute engine, current temperature of each compute engine, operating frequency of each compute engine, workload in the pipeline for each compute engine, power envelope of the computer system, maximum current IccMax of processor 110 and/or each compute engine 112, maximum power of processor 110 and/or each compute engine 112, aging and reliability measures of each compute engine, etc.

PMU 114 controls the power states of each compute engine 112 and also provides recommendations to memory controller 116 about power and/or performance states of memory module(s) 122. Examples of memory module(s) 122 are double data rate (DDR) compliant memory, low power DDR (LPDDR) compliant memory, static random-access memory (SRAM). In general, memories with comparatively lower memory space but faster exit times from low power state to active state comprise memory module(s) 122. Any suitable interface may be used to connect to memory module(s) 122.

Various embodiments here are described with reference to Cx states for processor states and Lx states for far memory states. Cx states correspond to states defined by the Advanced Configuration and Power Interface (ACPI) Specification (e.g., Version 6.2 Released May 2017), while Lx states pretrain to Peripheral Component Interconnect Express (PCIe) link states. Lx states are loosely referred to as the far memory states because a PCIe link (for example) connects processor 110 to a far memory (not shown). However, the embodiments are not limited to Cx states and Lx states. Other processor states and memory link states and/or memory power states may be used. For example, P-states, and S-states. In some embodiments, instead and/or in addition to using particular Cx, Lx, P, and/or S states, the multi-level memory can also be managed with reference states that represent responsiveness, computational intensive tasks, background tasks, etc.

C-states the idle (power saving) states. C-state x, Cx, means one or more subsystems of the CPU is at idle, powered down. C-states are states when the CPU has reduced or turned off selected functions. Different processors support different numbers of C-states in which various parts of the CPU are turned off.

P-states, also defined by the ACPI specification, provide a way to scale the frequency and voltage at which the processor runs so as to reduce the power consumption of the CPU. The number of available P-states can be different for each model of CPU, even those from the same family.

S-states are sleep states defined by the ACPI. S0 is a run or active state. In this state, the machine is fully running S1 is a suspend state. In this state, the CPU suspends activity but retain its contexts. S1 and S3 states are sleep states. In these states, memory contexts are held but CPU contexts are lost. The differences between S2 and S3 are in CPU re-initialization done by firmware and device re-initialization. S4 is a sleep state in which contexts are saved to a disk (e.g., far memory). The context is restored upon the return to S0 state. This is identical to soft-off for hardware. This state can be implemented by either OS or firmware. S5 is a soft-off state. All activity stops and all contexts are lost in this state. C0 is an active state, where CPU/Core is executing instructions. C1 is a Halt state where nothing is being executed, but it can return to C0 instantaneously. C2 is a stop-clock state, similar to C1 but it takes longer time to go back to C0. C3 is a sleep state. A processor can go back to C0 from C3 state, but it will take considerably longer time.

PCIe standards define four link power state levels that are software controlled: fully active state (L0), electrical idle or standby state (L0s), L1 (lower power standby/slumber state), L2 (low power sleep state), and L3 (link Off state).

As links transition from L0 to L3 states, both power saving and exit latencies increase. In the L0 state, the link is fully active in its ready mode and consumes the maximum active power. During short intervals of logical idle in absence of link activities, the link may transition into an L0s state with very low exit latencies (several hundred nanoseconds) for a small power reduction.

In the L1 state, all supplies and all reference clock components are fully active except as permitted by the clock power management when enabled. When the optional internal phase locked loop (PLL) is off or on, transmitter (Tx) and receiver (Rx) may be off or idle, and the common mode keeper remains active. Depending on the number of optional active devices in L1 state, power savings in the L1 standby mode can be limited and does not meet the requirements of mobile market as intended, even though the exit latencies of L1 state could be in the order of microseconds under certain conditions.

In the L2 sleep state, all clocks and main power supplies are turned off, providing the highest idle state power savings. However, exit latencies are very long, in the order of milliseconds, and not acceptable; therefore, the L2 power state is not commonly used in mobile applications.

In various embodiments, one or more memory resources of system 100—such as some or all of those at memory 120—are to be periodically charged (or “refreshed”) to help maintain a state of information which is currently stored with said one or more memory resources. For example, the one or more memory resources (and, for example, refresh manager circuitry such as that described herein) are provided at an IC chip, at a packaged device, or at a memory module which comprises one or more DRAM arrays. In one such embodiment, the memory module is a double data rate (DDR) synchronous dynamic random-access memory (SDRAM) module. To illustrate certain features of various embodiments, memory refresh and system throttling functionality are described herein with reference to the periodic charging of some or all memory cells of a first memory module 122. However, such description can be extended to apply to the periodic charging of any of various additional or alternative memory resources of system 100.

In an embodiment, circuitry of the first memory module 122 (or other circuitry of memory 120 which is coupled to the first memory module 122) provides functionality to request that the refreshing of the first memory module 122 be performed at particular rate (“refresh rate” herein)—e.g., wherein the requested refresh rate is determined based on information which specifies or otherwise indicates a current thermal state of the first memory module 122.

By way of illustration and not limitation, the first memory module 122 includes or is coupled to one or more thermal sensors (such as the illustrative thermal sensor 160 shown) which are operable to provide sensor information 162 which identifies one or more characteristics of a thermal state of the first memory module 122. In one such embodiment, sensor information 162 identifies one or more temperatures which are each at (or proximate to) a respective location of the first memory module 122. Alternatively or in addition, sensor information 162 identifies, for a given one such temperature, a rate of change (e.g., a first order rate, a second order rate, or the like) of said temperature.

In an embodiment, memory 120 comprises circuitry (such as that of the illustrative refresh management unit 124 shown) which identifies, based on the one or more thermal characteristic indicated by sensor information 162, a corresponding rate at which some or all memory cells of the first memory module 122 are to be refreshed. For example, refresh management unit 124 includes or otherwise has access to reference information which identifies a correspondence of various thermal conditions each with a different respective refresh rate. In various embodiments, the reference information is provided by a manufacturer, a distributor, a system administrator, a user, performance monitor logic and/or any of various other suitable agents. Based on sensor information 162, refresh management unit 124 performs a lookup or other access of the reference information to identify a refresh rate to be requested. In an embodiment, the provisioning, access and/or use of such reference information includes operations which (for example) are adapted from conventional memory operation techniques, which are not limiting on some embodiments, and are not detailed herein to avoid obscuring features of said embodiments. In some embodiments, the first memory module 122 comprises refresh management unit 124.

In an embodiment, refresh management unit 124 requests that memory cells of the first memory module 122 be refreshed at the rate which is identified based on sensor information 162. In one such embodiment, refresh management unit 124 requests that an external agent (such as a counterpart refresh management unit 118 of memory controller 116) provide memory refreshes to the first memory module 122 at the identified rate. In an alternative embodiment, refresh management unit 124 requests that internal circuitry of memory 120 (e.g., of the first memory module 122) perform self-refresh operations at the identified rate. In various embodiments, refresh management unit 124 (and/or other suitable circuitry of memory 120) communicates to one or more external agents—e.g., including memory controller 116 and/or PMU 114) that the first memory module 122 is to be refreshed—or is being self-refreshed—at the identified rate.

For example, refresh management unit 124 successively identifies to an external agent different requested refresh rates—e.g., as the thermal state of the first memory module 122 changes over time. In one such embodiment, refresh management unit 124 requests an increased refresh rate based on sensor information 162 providing an indication of an increased temperature of the first memory module 122, and/or requests a decreased refresh rate based on sensor information 162 indicating of a decreased temperature.

In various embodiments, some or all of memory 120 is refreshed by an external agent such as memory controller 116. For example, memory controller 116 is operable to refresh memory cells of the first memory module 122—e.g., based on memory 120 proving to memory controller 116 an identifier of the requested refresh rate. In one such embodiment, memory controller 116 forwards, relays or otherwise provides to PMU 114 an identifier of the requested refresh rate—e.g., wherein PMU 114 is updated with the most recently requested refresh rate for the first memory module 122. In an alternative embodiment, PMU 114 is updated with the most recently requested refresh rate via a path which is independent of memory controller 116 (and/or concurrent with memory 120 providing a self-refreshing of the first memory module 122).

In one such embodiment, PMU 114 is further coupled to receive an identifier of a threshold maximum refresh rate which, for example, is communicated via one of IO devices 140a, . . . , 140x, from OS 130 (e.g., based on user controls 131 and/or applications 132) and/or from any of various other suitable agents. For example, the threshold maximum refresh rate is stored in a repository 115 of one or more operational parameters which are to determine power management at least in part. In an illustrative scenario according to one embodiment, the threshold maximum refresh rate is provided to PMU 114 by a manufacturer, distributor, administrator, use or other suitable agent. In some embodiments, a threshold maximum refresh rate is provided as a posteriori information—e.g., wherein such embodiments are not limited with respect to particular techniques by which the threshold maximum refresh rate is generated and/or provisioned to system 100.

In various embodiments, PMU 114 performs an evaluation-based on both a requested refresh rate for the first memory module 122 and the threshold maximum refresh rate identified at repository 115—to determine whether one or more operations of system 100 are to be throttled to mitigate a heating of the first memory module 122. In one embodiment, any such throttling is to be performed while the first memory module 122 continues to be refreshed at the requested refresh rate.

By way of illustration and not limitation, PMU 114 performs a comparison of the requested refresh rate with the threshold maximum refresh rate—e.g., wherein PMU 114 selectively generates one or more control signals to implement a throttling action where it is determined, for example, that the requested refresh rate is greater than (or, in some embodiments, equal to) the threshold refresh rate. Alternatively or in addition, PMU 114 makes a determination to forego any such throttling (or, for example, to mitigate some previously-implemented throttling) where it is instead determined that the requested refresh rate is less than the threshold maximum refresh rate. In an illustrative scenario according to one embodiment, PMU 114 identifies a next power state to be implemented based on a difference between the current requested refresh rate and the threshold maximum refresh rate—e.g., wherein PMU 114 initiates a throttling action by transitioning some or all of system 100 from a current power state to the identified next power state.

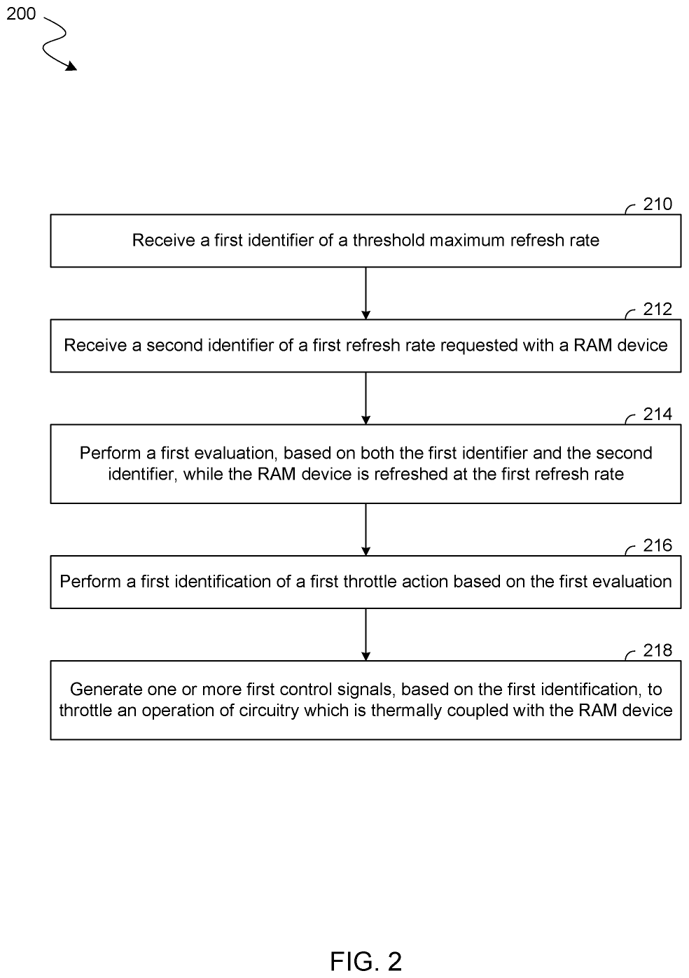

FIG. 2 shows a method 200 for performing thermal regulation based on refresh rate information according to an embodiment. Method 200 illustrates one example of an embodiment wherein circuitry, which is thermally coupled to a memory device (such as a DDR module), is selectively throttled based on both a threshold maximum refresh rate and a requested rate for refreshing the memory device. Operations such as those of method 200 are performed with any of various combinations of suitable hardware (e.g., circuitry), firmware and/or executing software which, for example, provide some or all of the functionality of PMU 114.

As shown in FIG. 2, method 200 comprises (at 210) receiving a first identifier of a threshold maximum refresh rate. For example, the first identifier is provide to repository 115—e.g., wherein the first identifier is provided to PMU 114 with OS 130, with one of IO devices 140a, . . . , 140x, or with any of various other suitable agents. Method 200 further comprises (at 212) receiving a second identifier of a first refresh rate requested with a RAM device. In various embodiments, the second identifier is provided via a memory controller by which power management logic, which performs method 200, is coupled to the RAM device.

While the RAM device is refreshed at the first refresh rate, method 200 (at 214) further performs a first evaluation based on both the first identifier and the second identifier. In one such embodiment, performing the first evaluation at 214 comprises identifying a first difference between the threshold maximum refresh rate and the first refresh rate. Based on the first evaluation at 214, method 200 (at 216) further performs a first identification of a first throttle action which is to be performed. For example, the first identification is performed at 216 based on the first evaluation at 214 determining that the first refresh rate is greater than (or equal to, for example) the threshold maximum refresh rate.

In some embodiments, performing the first identification at 216 comprises performing a search of reference information, based on the difference, to identify a power state. For example, the reference information identifies multiple refresh states as corresponding each to a different respective one of multiple power states. In one such embodiment, the multiple refresh states each comprise a respective difference between the threshold maximum refresh rate and a different respective refresh rate. Based on the search of the reference information, method identifies a next power state to be implemented (or, for example, a throttle operation to be performed as part of the currently implemented power state).

Based on the first identification performed at 216, method 200 (at 218) generates one or more first control signals to throttle an operation of circuitry which is thermally coupled with the RAM device. By way of illustration and not limitation, the one or more first control signals are to perform dynamic voltage and frequency scaling of a memory controller which is coupled to provide access to the RAM device. Alternatively or in addition, the one or more first control signals are to perform dynamic voltage and frequency scaling of one or more compute engines (processor cores, for example) which are each coupled to access to the RAM device—e.g., via the memory controller. Alternatively or in addition, the one or more first control signals are to prevent an execution of a software process by the one or more compute engines. In various embodiments, the the RAM device continues to be refreshed at the first refresh rate after the operation is throttled based on the one or more first control signals.

In various embodiments, operations similar to those shown for method 200 are successively performed multiple times—e.g., to determine whether an additional throttle action is to be selectively performed, or whether a previously implement throttle action is to be selectively stopped or otherwise mitigated. In one such embodiment, this determining is performed based on another evaluation based on both the first identifier and the third identifier—e.g., wherein the RAM device continues to be refreshed at the second refresh rate after additional throttle action is performed (or after a previously implement throttle action is mitigated).

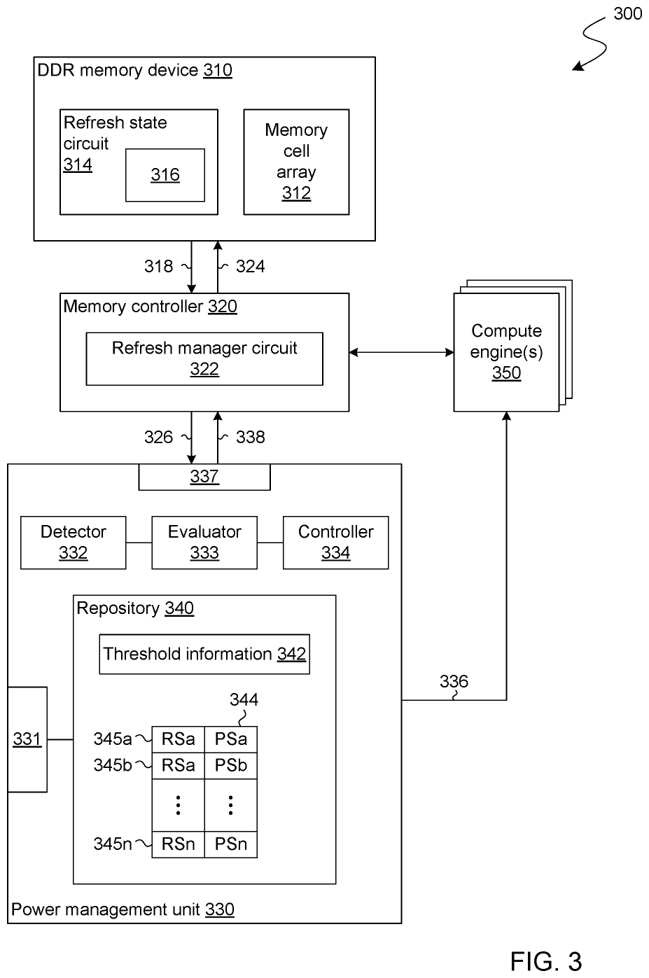

FIG. 3 shows a device 300 which throttles operations based on refresh rate information according to an embodiment. Device 300 illustrates features of one example embodiment which determines, based on an identifier of a requested refresh rate and another identifier of a threshold maximum refresh rate, whether one or more throttling actions are to be performed to mitigate a conduction of heat with a memory device. In some embodiments, device 300 provides functionality such as that of system 100—e.g., wherein operations of method 200 are performed with some or all of device 300.

As shown in FIG. 3, device 300 comprises a DRAM device 310, a memory controller 320, a power management unit 330, and one or more compute engines 350 which, for example, correspond functionally to memory 120, memory controller 116, PMU 114, and one or more compute engines 112 (respectively). In one such embodiment, DRAM device 310 comprises an array 312 of DRAM memory cells which need to be periodically refreshed over time. DRAM device 310 further comprises a refresh state circuit 314 (providing functionality of refresh management unit 124, for example) which is coupled to receive or otherwise detect state information that specifies or otherwise indicates a thermal condition at a location of DRAM device 310. In an embodiment, refresh state circuit 314 includes or otherwise has access to reference information 316 which defines, for each of various thermal conditions (e.g., each of various temperature levels) a different respective refresh rate which is to be requested in the event that said thermal condition is indicated by the state information.

Based on a given thermal condition which is indicated by the state information, refresh state circuit 314 performs a lookup or other suitable access of reference information 316 to identify a corresponding rate which is to be requested for refreshing of memory cell array 312. In one such embodiment, refresh state circuit 314 (or other suitable logic of DRAM device 310) outputs a signal 318 to request the identified refresh rate—e.g., wherein, based on signal 318, a refresh manager circuit 322 of memory controller 320 controls the generation of a refresh signal 324 to periodically charge memory cell array 312 at the requested rate. In another embodiment, refresh state circuit 314 requests other circuitry of DRAM device 310 to perform a self-refresh of memory cell array 312 at the identified rate—e.g., wherein signal 318 is also generated to identify the requested self-refresh rate to memory controller 320.

In an embodiment, power management unit 330 is coupled—e.g., via a hardware interface 337—to receive from memory controller 320 a signal 326 which comprises an identifier of the requested refresh rate. In an alternative embodiment, power management unit 330 receives such an identifier from DRAM device 310 via a path which is independent of memory controller 320.

In one such embodiment, power management unit 330 is further coupled to receive—e.g., via an interface 331—an identifier of a threshold maximum memory refresh rate. Such a threshold maximum refresh rate is maintained at power management unit 330, for example, a threshold information 342 in a repository 340 (such as repository 115) of operational parameters for determining power management. In an embodiment, repository 340 is further to store reference information (such as that in the illustrative table 344 shown) which identifies, for each of multiple refresh states, a corresponding power state to be provided in the event of such a refresh state.

By way of illustration and not limitation, an entry 345a of table 344 identifies a correspondence of a refresh state RSa to a power state PSa. Furthermore, an entry 345b of table 344 identifies a correspondence of a refresh state RSb to a power state PSb. Further still, an entry 345n of table 344 identifies a correspondence of a refresh state RSn to a power state PSn. In an illustrative scenario according to one embodiment, a given one of refresh states RSa, RSb, . . . , RSx includes, or is otherwise based on, a difference between the threshold maximum refresh rate and a different respective refresh rate which DRAM device 310 could request. Alternatively or in addition, a given one of power states PSa, PSb, . . . , PSx comprises an operational frequency, a level of a supply voltage, a maximum allowable workload, a number of compute engines (e.g., cores) to be active, and/or any of various other suitable operational characteristics.

In various embodiments, power management unit 330 performs an evaluation-based on both a requested refresh rate and the threshold maximum refresh rate identified by threshold information 342—to determine whether one or more operations of device 300 are to be throttled to mitigate a heating of DRAM device 310. In one embodiment, any such throttling is to be performed while memory cell array 312 continues to be refreshed at the requested refresh rate.

By way of illustration and not limitation, PMU 114 performs a comparison of the requested refresh rate with the threshold maximum refresh rate—e.g., wherein PMU 114 selectively generates one or more control signals to implement a throttling action where it is determined, for example, that the requested refresh rate is greater than (or, in some embodiments, equal to) the threshold refresh rate. Alternatively or in addition, PMU 114 makes a determination to forego any such throttling (or, for example, to mitigate some previously-implemented throttling) where it is instead determined that the requested refresh rate is less than the threshold maximum refresh rate. In an illustrative scenario according to one embodiment, PMU 114 identifies a next power state to be implemented based on a difference between the current requested refresh rate and the threshold maximum refresh rate—e.g., wherein PMU 114 initiates a throttling action by transitioning some or all of system 100 from a current power state to the identified next power state.

In one illustrative embodiment, a detector 332 of power management unit 330 receives the identifier of the requested refresh rate (e.g., as provided via refresh rate signal 326). In one such embodiment, detector 332 performs a comparison—e.g., including a subtraction and/or other suitable calculation—to detect whether the requested refresh rate is greater than (or equal to, in some embodiments) the threshold maximum refresh rate. Based on a refresh state detected by detector 332 (e.g., the refresh state comprising a calculated difference between the requested refresh rate and the threshold maximum refresh rate), an evaluator 333 of power management unit 330 performs a lookup or other suitable access of table 344 to identify a corresponding power state which is to be implemented. In an embodiment, evaluator 333 specifies or otherwise indicates the identified power state to a controller 334 of power management unit 330—e.g., wherein controller 334 is operable to selectively throttle one or more operations which (for example) are performed with some or all of DRAM device 310, memory controller 320, and compute engine(s) 350.

By way of illustration and not limitation, controller 334 generates one or more power management control signals (such as the illustrative control signal 336 shown) to facilitate a throttling action comprising dynamic voltage and frequency scaling (DVFS) of compute engine(s) 350—e.g., wherein control signal 336 lowers an operational frequency of compute engine(s) 350 and/or lowers a supply voltage which is provided to compute engine(s) 350. Alternatively or in addition, control signal 336 suspends, cancels or otherwise stops one or more software processes and/or other tasks being performed with compute engine(s) 350.

Alternatively or in addition, a throttling action is initiated by controller 334 communicating one or more other control signals (such as the illustrative control signal 338 shown) to initiate DVFS of memory controller 320. In some embodiments, any of various additional or alternative throttling actions are performed based on the refresh state which is identified by detector 332. By way of illustration and not limitation, some or all such throttling actions comprise operations that (for example) are adapted from conventional power management techniques.

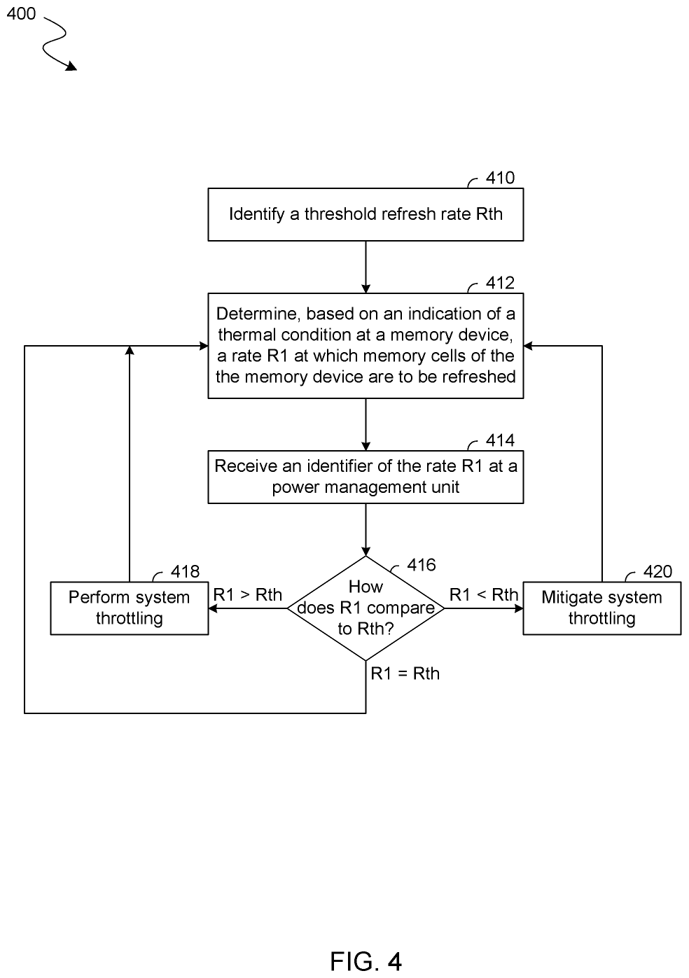

FIG. 4 shows a method 400 for providing thermal regulation of a memory based on a threshold refresh rate according to an embodiment. Method 400 illustrates one example of an embodiment wherein throttling is variously performed and mitigated as an indicated temperature of a memory device changes at different times. Operations such as those of method 400 are performed with logic such as that of system 100 or device 300—e.g., wherein method 400 comprises some or all of method 200.

As shown in FIG. 4, method 400 comprises (at 410) identifying a threshold refresh rate Rth such as one which is provided at repository 115 or threshold information 342. Method 400 further comprises (at 412) determining, based on an indication of a thermal condition at a memory device, a rate R1 at which memory cells of the memory device are to be refreshed. In an embodiment, the rate R1 is a rate which has been (or is to be) requested for refreshes (for example, self-refreshes) of the memory device. In some alternate embodiments, method 400 omits the determining at 412—e.g., wherein method 400 is performed by power management logic, and wherein a memory device (which is coupled to the power management logic) performs such determining.

Method 400 further comprises (at 414) receiving an identifier of the requested refresh rate R1 at a power management unit—e.g., wherein memory 120 provides the identifier to processor 110, wherein DRAM device 310 provides the identifier to power management unit 330, or the like. Method 400 further comprises performing an evaluation (at 416) to determine how the requested refresh rate R1 compares to the threshold refresh rate Rth. Where it is determined at 416 that the requested refresh rate R1 is greater than the threshold refresh rate Rth, method 400 (at 418) begins to perform a throttling of the system which conducts heat with the memory device. After the throttling has begun at 418, method 400 performs a next instance of the determining at 412.

Where it is instead determined at 416 that the requested refresh rate R1 is less than the threshold refresh rate Rth, method 400 (at 420) mitigates a throttling of the system which conducts heat to the memory device. After the mitigating at 418 has begun, method 400 performs a next instance of the determining at 412. Where it is instead determined at 416 that the requested refresh rate R1 is equal to the threshold refresh rate Rth, method 400 performs a next instance of the determining at 412—i.e., without beginning (or, for example, without changing or stopping) any previous system throttling that might be performed by method 400.

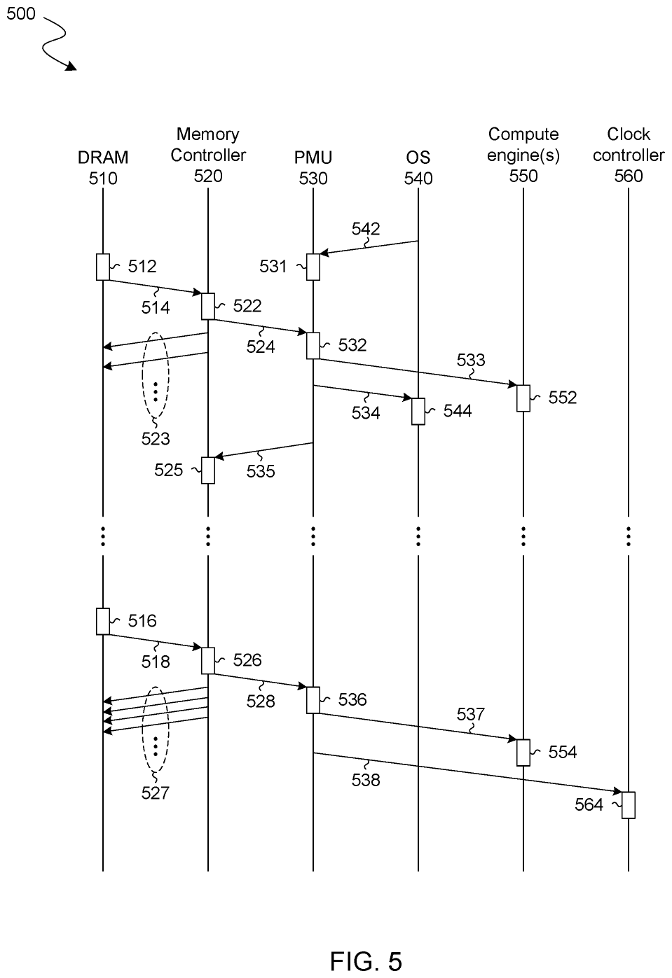

FIG. 5 shows a swim lane diagram 500 illustrating operations and communications which are performed to regulate a temperature of a memory device based on a threshold refresh rate according to an embodiment. Communications such as those illustrated in swim lane diagram 500 are performed (for example) with circuitry and/or other logic of system 100 or device 300—e.g., wherein operations of one of methods 200, 400 are based on (for example, include), or result in, some or all such communications.

As shown in FIG. 5, swim lane diagram 500 illustrates operations and communications which are variously performed with a dynamic random access memory (DRAM) 510, a memory controller 520, a power management unit (PMU) 530, an operating system (OS) 540, one or more compute engines 550, and a clock controller 560. By way of illustration and not limitation, DRAM 510, memory controller 520, PMU 530, OS 540, and one or more compute engines 550 variously provide functionality such as that of the first memory module 122, memory controller 116, PMU 114, OS 130, and one or more compute engines 112 (respectively). Clock controller 560 illustrates one of various suitable resources which are (re) configurable, responsive to PMU 530, to provide (at least in part) any of multiple possible power states, or to otherwise facilitate throttling of circuitry which conducts heat with DRAM 510.

In the example embodiment shown, OS 540 sends to PMU 530 a signal 542 which comprises an identifier of a threshold maximum rate (Rth) at which some or all memory cells of DRAM 510 are to be refreshed. Based on signal 542, PMU 530 performs operations 531 to save the identifier of the threshold maximum refresh rate Rth for later use in determining whether a throttling action is to be performed.

At some point (e.g., after PMU 530 has identified the threshold refresh rate Rth), DRAM 510 performs operations 512 to identify a refresh rate R1 based on an indication of a thermal condition which is at (or proximate to) DRAM 510. In some embodiments, the refresh rate R1 is identified to internal circuitry of DRAM 510 in a request for self-refresh operations. Alternatively, the refresh rate R1 is to be requested for refreshing of DRAM 510 by memory controller 520 and/or other suitable circuitry which is external to DRAM 510.

Based on operations 512, DRAM 510 sends a signal 514 which identifies the requested refresh rate R1 to memory controller 520. In turn, memory controller 520 sends a signal 524 which communicates to PMU 530 the requested refresh rate R1 identified by signal 514. In various embodiments, memory controller 520 performs operations 522 to configure a refreshing of DRAM 510 based on signal 514—e.g., wherein refresh charges 523 are provided from memory controller 520 to DRAM 510 at the identified refresh rate R1.

Based on the threshold maximum refresh rate Rth identified by signal 542 and the requested refresh rate R1 identified by signal 524, PMU 530 performs operations 532 to evaluate whether a throttling action is to be performed—e.g., to mitigate a conduction of heat to, or within, DRAM 510. In one such embodiment, operations 532 comprises evaluating whether the requested refresh rate R1 is greater than (or equal to, in some embodiments) the threshold maximum refresh rate Rth. In the example embodiment shown, the evaluation by operations 532 results in a determination that one or more operations are to be throttled—e.g., wherein PMU 530 generates one or more more control signals to initiate such throttling.

By way of illustration and not limitation, PMU 530 sends a signal 533 to indicate to the one or more compute engines 550 that (for example) one or more software processes are to be suspended, exited, canceled or otherwise prevented—e.g., wherein the one or more compute engines 550 perform throttling operations 552 based on signal 533. Alternatively or in addition, PMU 530 sends a signal 534 to indicate to OS 540 that any of various throttling operations have been performed, and/or that one or more throttling operations 544 (e.g., comprising core parking or the like) are to be performed with OS 540. Alternatively or in addition, PMU 530 sends a signal 535 to initiate one or more operations 525 which throttle memory controller 520.

In one such embodiment, DRAM 510 subsequently performs additional operations 516 which—for example—identify a higher refresh rate R2 based on an indication of an increased temperature at (or proximate to) DRAM 510. Based on operations 516, DRAM 510 sends a signal 518 which identifies a new requested refresh rate R2 to memory controller 520. In turn, memory controller 520 sends a signal 528 to communicate to PMU 530 the requested refresh rate R2 which is identified by signal 518. In various embodiments, memory controller 520 performs operations 526 to configure a refreshing of DRAM 510 based on signal 518—e.g., wherein refresh charges 527 are provided from memory controller 520 to DRAM 510 at the identified refresh rate R2.

Based on the threshold maximum refresh rate Rth identified by signal 542, and further based on the requested refresh rate R2 identified by signal 528, PMU 530 performs operations 536 to evaluate whether another throttling action is to be performed or (for example) whether the earlier throttling action is to be stopped or otherwise mitigated. In the example embodiment shown, the evaluation by operations 536 results in a determination that one or more operations are to be further throttled—e.g., wherein the operations 536 determine that requested refresh rate R2 is greater than (or, for example, is equal to) the threshold maximum refresh rate Rth.

By way of illustration and not limitation, PMU 530 sends a signal 537 to indicate to the one or more compute engines 550 that (for example) one or more software processes are to be suspended, or otherwise prevented—e.g., wherein the one or more compute engines 550 perform throttling operations 554 based on signal 537. Alternatively or in addition, PMU 530 sends a signal 538 for clock controller 560 to begin operations 564 which decrease the respective frequencies of one or more clock signals—e.g., to reduce an operational frequency of the one or more compute engines 550.

### Exemplary Computer Architectures.

Detailed below are describes of exemplary computer architectures. Other system designs and configurations known in the arts for laptop, desktop, and handheld personal computers (PC) s, personal digital assistants, engineering workstations, servers, disaggregated servers, network devices, network hubs, switches, routers, embedded processors, digital signal processors (DSPs), graphics devices, video game devices, set-top boxes, micro controllers, cell phones, portable media players, hand-held devices, and various other electronic devices, are also suitable. In general, a variety of systems or electronic devices capable of incorporating a processor and/or other execution logic as disclosed herein are generally suitable.

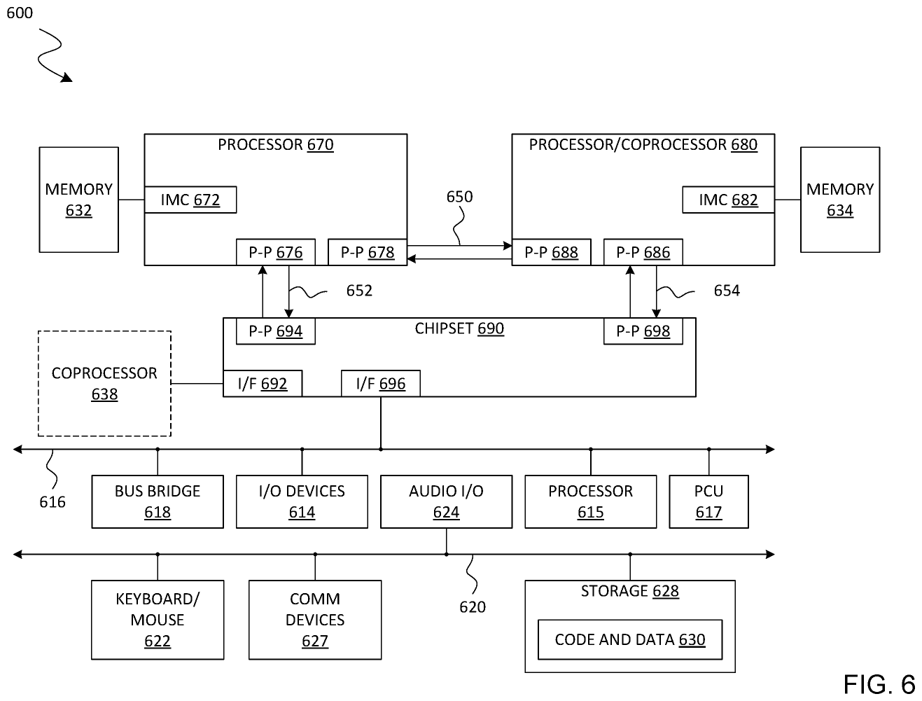

FIG. 6 illustrates an exemplary system. Multiprocessor system 600 is a point-to-point interconnect system and includes a plurality of processors including a first processor 670 and a second processor 680 coupled via a point-to-point interconnect 650. In some examples, the first processor 670 and the second processor 680 are homogeneous. In some examples, first processor 670 and the second processor 680 are heterogenous. Though the exemplary system 600 is shown to have two processors, the system may have three or more processors, or may be a single processor system.

Processors 670 and 680 are shown including integrated memory controller (IMC) circuitry 672 and 682, respectively. Processor 670 also includes as part of its interconnect controller point-to-point (P-P) interfaces 676 and 678; similarly, second processor 680 includes P-P interfaces 686 and 688. Processors 670, 680 may exchange information via the point-to-point (P-P) interconnect 650 using P-P interface circuits 678, 688. IMCs 672 and 682 couple the processors 670, 680 to respective memories, namely a memory 632 and a memory 634, which may be portions of main memory locally attached to the respective processors.

Processors 670, 680 may each exchange information with a chipset 690 via individual P-P interconnects 652, 654 using point to point interface circuits 676, 694, 686, 698. Chipset 690 may optionally exchange information with a coprocessor 638 via an interface 692. In some examples, the coprocessor 638 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 670, 680 or outside of both processors, yet connected with the processors via P-P interconnect, such that either or both processors' local cache information may be stored in the shared cache if a processor is placed into a low power mode.

Chipset 690 may be coupled to a first interconnect 616 via an interface 696. In some examples, first interconnect 616 may be a Peripheral Component Interconnect (PCI) interconnect, or an interconnect such as a PCI Express interconnect or another I/O interconnect. In some examples, one of the interconnects couples to a power control unit (PCU) 617, which may include circuitry, software, and/or firmware to perform power management operations with regard to the processors 670, 680 and/or co-processor 638. PCU 617 provides control information to a voltage regulator (not shown) to cause the voltage regulator to generate the appropriate regulated voltage. PCU 617 also provides control information to control the operating voltage generated. In various examples, PCU 617 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 617 is illustrated as being present as logic separate from the processor 670 and/or processor 680. In other cases, PCU 617 may execute on a given one or more of cores (not shown) of processor 670 or 680. In some cases, PCU 617 may be implemented as a microcontroller (dedicated or general-purpose) or other control logic configured to execute its own dedicated power management code, sometimes referred to as P-code. In yet other examples, power management operations to be performed by PCU 617 may be implemented externally to a processor, such as by way of a separate power management integrated circuit (PMIC) or another component external to the processor. In yet other examples, power management operations to be performed by PCU 617 may be implemented within BIOS or other system software.

Various I/O devices 614 may be coupled to first interconnect 616, along with a bus bridge 618 which couples first interconnect 616 to a second interconnect 620. In some examples, one or more additional processor(s) 615, such as coprocessors, high-throughput many integrated core (MIC) processors, GPGPUs, accelerators (such as graphics accelerators or digital signal processing (DSP) units), field programmable gate arrays (FPGAs), or any other processor, are coupled to first interconnect 616. In some examples, second interconnect 620 may be a low pin count (LPC) interconnect. Various devices may be coupled to second interconnect 620 including, for example, a keyboard and/or mouse 622, communication devices 627 and a storage circuitry 628. Storage circuitry 628 may be one or more non-transitory machine-readable storage media as described below, such as a disk drive or other mass storage device which may include instructions/code and data 630 in some examples. Further, an audio I/O 624 may be coupled to second interconnect 620. Note that other architectures than the point-to-point architecture described above are possible. For example, instead of the point-to-point architecture, a system such as multiprocessor system 600 may implement a multi-drop interconnect or other such architecture.

### Exemplary Core Architectures, Processors, and Computer Architectures.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may include on the same die as the described CPU (sometimes referred to as the application core(s) or application processor(s)), the above described coprocessor, and additional functionality. Exemplary core architectures are described next, followed by descriptions of exemplary processors and computer architectures.

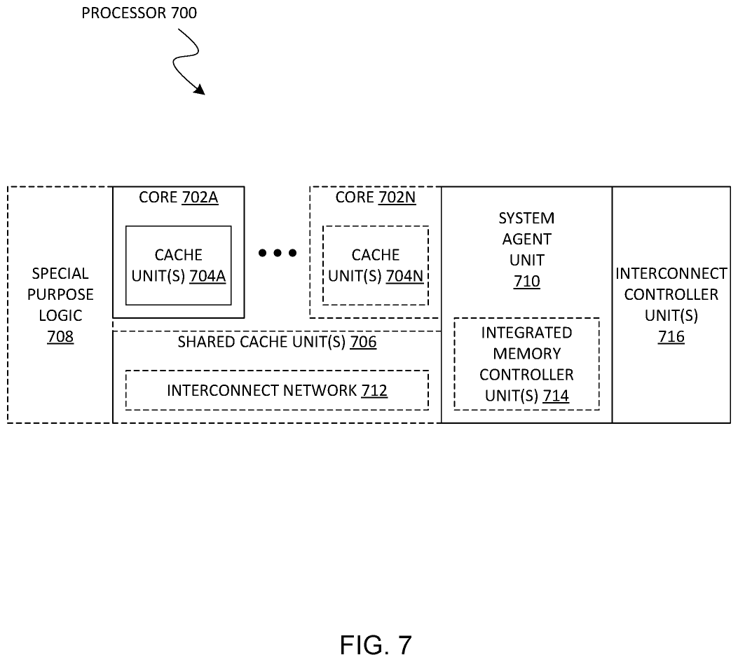

FIG. 7 illustrates a block diagram of an example processor 700 that may have more than one core and an integrated memory controller. The solid lined boxes illustrate a processor 700 with a single core 702A, a system agent unit circuitry 710, a set of one or more interconnect controller unit(s) circuitry 716, while the optional addition of the dashed lined boxes illustrates an alternative processor 700 with multiple cores 702A-N, a set of one or more integrated memory controller unit(s) circuitry 714 in the system agent unit circuitry 710, and special purpose logic 708, as well as a set of one or more interconnect controller units circuitry 716. Note that the processor 700 may be one of the processors 670 or 680, or co-processor 638 or 615 of FIG. 6.

Thus, different implementations of the processor 700 may include: 1) a CPU with the special purpose logic 708 being integrated graphics and/or scientific (throughput) logic (which may include one or more cores, not shown), and the cores 702A-N being one or more general purpose cores (e.g., general purpose in-order cores, general purpose out-of-order cores, or a combination of the two); 2) a coprocessor with the cores 702A-N being a large number of special purpose cores intended primarily for graphics and/or scientific (throughput); and 3) a coprocessor with the cores 702A-N being a large number of general purpose in-order cores. Thus, the processor 700 may be a general-purpose processor, coprocessor or special-purpose processor, such as, for example, a network or communication processor, compression engine, graphics processor, GPGPU (general purpose graphics processing unit circuitry), a high-throughput many integrated core (MIC) coprocessor (including 30 or more cores), embedded processor, or the like. The processor may be implemented on one or more chips. The processor 700 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 704A-N within the cores 702A-N, a set of one or more shared cache unit(s) circuitry 706, and external memory (not shown) coupled to the set of integrated memory controller unit(s) circuitry 714. The set of one or more shared cache unit(s) circuitry 706 may include one or more mid-level caches, such as level 2 (L2), level 3 (L3), level 4 (L4), or other levels of cache, such as a last level cache (LLC), and/or combinations thereof. While in some examples ring-based interconnect network circuitry 712 interconnects the special purpose logic 708 (e.g., integrated graphics logic), the set of shared cache unit(s) circuitry 706, and the system agent unit circuitry 710, alternative examples use any number of well-known techniques for interconnecting such units. In some examples, coherency is maintained between one or more of the shared cache unit(s) circuitry 706 and cores 702A-N.

In some examples, one or more of the cores 702A-N are capable of multi-threading. The system agent unit circuitry 710 includes those components coordinating and operating cores 702A-N. The system agent unit circuitry 710 may include, for example, power control unit (PCU) circuitry and/or display unit circuitry (not shown). The PCU may be or may include logic and components needed for regulating the power state of the cores 702A-N and/or the special purpose logic 708 (e.g., integrated graphics logic). The display unit circuitry is for driving one or more externally connected displays.

The cores 702A-N may be homogenous in terms of instruction set architecture (ISA). Alternatively, the cores 702A-N may be heterogeneous in terms of ISA; that is, a subset of the cores 702A-N may be capable of executing an ISA, while other cores may be capable of executing only a subset of that ISA or another ISA.

### Exemplary Core Architectures-In-Order and Out-of-Order Core Block Diagram.

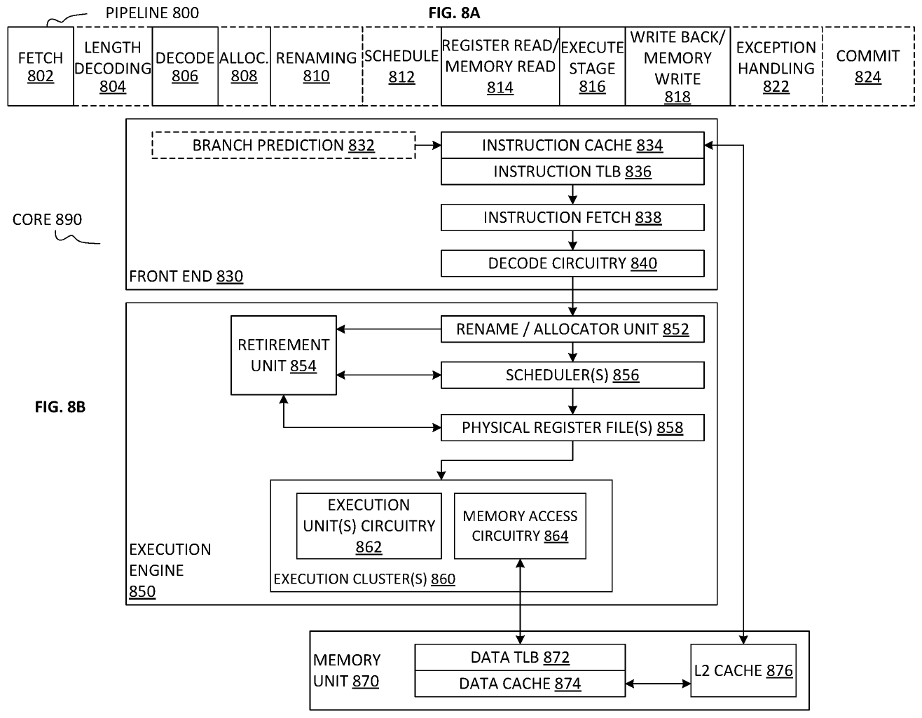

FIG. 8A is a block diagram illustrating both an exemplary in-order pipeline and an exemplary register renaming, out-of-order issue/execution pipeline according to examples. FIG. 8B is a block diagram illustrating both an exemplary example of an in-order architecture core and an exemplary register renaming, out-of-order issue/execution architecture core to be included in a processor according to examples. The solid lined boxes in FIGS. 8A-B illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 8A, a processor pipeline 800 includes a fetch stage 802, an optional length decoding stage 804, a decode stage 806, an optional allocation (Alloc) stage 808, an optional renaming stage 810, a schedule (also known as a dispatch or issue) stage 812, an optional register read/memory read stage 814, an execute stage 816, a write back/memory write stage 818, an optional exception handling stage 822, and an optional commit stage 824. One or more operations can be performed in each of these processor pipeline stages. For example, during the fetch stage 802, one or more instructions are fetched from instruction memory, and during the decode stage 806, the one or more fetched instructions may be decoded, addresses (e.g., load store unit (LSU) addresses) using forwarded register ports may be generated, and branch forwarding (e.g., immediate offset or a link register (LR)) may be performed. In one example, the decode stage 806 and the register read/memory read stage 814 may be combined into one pipeline stage. In one example, during the execute stage 816, the decoded instructions may be executed, LSU address/data pipelining to an Advanced Microcontroller Bus (AMB) interface may be performed, multiply and add operations may be performed, arithmetic operations with branch results may be performed, etc.

By way of example, the exemplary register renaming, out-of-order issue/execution architecture core of FIG. 8B may implement the pipeline 800 as follows: 1) the instruction fetch circuitry 838 performs the fetch and length decoding stages 802 and 804; 2) the decode circuitry 840 performs the decode stage 806; 3) the rename/allocator unit circuitry 852 performs the allocation stage 808 and renaming stage 810; 4) the scheduler(s) circuitry 856 performs the schedule stage 812; 5) the physical register file(s) circuitry 858 and the memory unit circuitry 870 perform the register read/memory read stage 814; the execution cluster(s) 860 perform the execute stage 816; 6) the memory unit circuitry 870 and the physical register file(s) circuitry 858 perform the write back/memory write stage 818; 7) various circuitry may be involved in the exception handling stage 822; and 8) the retirement unit circuitry 854 and the physical register file(s) circuitry 858 perform the commit stage 824.

FIG. 8B shows a processor core 890 including front-end unit circuitry 830 coupled to an execution engine unit circuitry 850, and both are coupled to a memory unit circuitry 870. The core 890 may be a reduced instruction set architecture computing (RISC) core, a complex instruction set architecture computing (CISC) core, a very long instruction word (VLIW) core, or a hybrid or alternative core type. As yet another option, the core 890 may be a special-purpose core, such as, for example, a network or communication core, compression engine, coprocessor core, general purpose computing graphics processing unit (GPGPU) core, graphics core, or the like.

The front end unit circuitry 830 may include branch prediction circuitry 832 coupled to an instruction cache circuitry 834, which is coupled to an instruction translation lookaside buffer (TLB) 836, which is coupled to instruction fetch circuitry 838, which is coupled to decode circuitry 840. In one example, the instruction cache circuitry 834 is included in the memory unit circuitry 870 rather than the front-end circuitry 830. The decode circuitry 840 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 840 may further include an address generation unit (AGU, not shown) circuitry. In one example, the AGU generates an LSU address using forwarded register ports, and may further perform branch forwarding (e.g., immediate offset branch forwarding, LR register branch forwarding, etc.). The decode circuitry 840 may be implemented using various different mechanisms. Examples of suitable mechanisms include, but are not limited to, look-up tables, hardware implementations, programmable logic arrays (PLAs), microcode read only memories (ROMs), etc. In one example, the core 890 includes a microcode ROM (not shown) or other medium that stores microcode for certain macroinstructions (e.g., in decode circuitry 840 or otherwise within the front end circuitry 830). In one example, the decode circuitry 840 includes a micro-operation (micro-op) or operation cache (not shown) to hold/cache decoded operations, micro-tags, or micro-operations generated during the decode or other stages of the processor pipeline 800. The decode circuitry 840 may be coupled to rename/allocator unit circuitry 852 in the execution engine circuitry 850.

The execution engine circuitry 850 includes the rename/allocator unit circuitry 852 coupled to a retirement unit circuitry 854 and a set of one or more scheduler(s) circuitry 856. The scheduler(s) circuitry 856 represents any number of different schedulers, including reservations stations, central instruction window, etc. In some examples, the scheduler(s) circuitry 856 can include arithmetic logic unit (ALU) scheduler/scheduling circuitry, ALU queues, arithmetic generation unit (AGU) scheduler/scheduling circuitry, AGU queues, etc. The scheduler(s) circuitry 856 is coupled to the physical register file(s) circuitry 858. Each of the physical register file(s) circuitry 858 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In one example, the physical register file(s) circuitry 858 includes vector registers unit circuitry, writemask registers unit circuitry, and scalar register unit circuitry. These register units may provide architectural vector registers, vector mask registers, general-purpose registers, etc. The physical register file(s) circuitry 858 is coupled to the retirement unit circuitry 854 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 854 and the physical register file(s) circuitry 858 are coupled to the execution cluster(s) 860. The execution cluster(s) 860 includes a set of one or more execution unit(s) circuitry 862 and a set of one or more memory access circuitry 864. The execution unit(s) circuitry 862 may perform various arithmetic, logic, floating-point or other types of operations (e.g., shifts, addition, subtraction, multiplication) and on various types of data (e.g., scalar integer, scalar floating-point, packed integer, packed floating-point, vector integer, vector floating-point). While some examples may include a number of execution units or execution unit circuitry dedicated to specific functions or sets of functions, other examples may include only one execution unit circuitry or multiple execution units/execution unit circuitry that all perform all functions. The scheduler(s) circuitry 856, physical register file(s) circuitry 858, and execution cluster(s) 860 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) circuitry, and/or execution cluster—and in the case of a separate memory access pipeline, certain examples are implemented in which only the execution cluster of this pipeline has the memory access unit(s) circuitry 864). It should also be understood that where separate pipelines are used, one or more of these pipelines may be out-of-order issue/execution and the rest in-order.

In some examples, the execution engine unit circuitry 850 may perform load store unit (LSU) address/data pipelining to an Advanced Microcontroller Bus (AMB) interface (not shown), and address phase and writeback, data phase load, store, and branches.

The set of memory access circuitry 864 is coupled to the memory unit circuitry 870, which includes data TLB circuitry 872 coupled to a data cache circuitry 874 coupled to a level 2 (L2) cache circuitry 876. In one exemplary example, the memory access circuitry 864 may include a load unit circuitry, a store address unit circuit, and a store data unit circuitry, each of which is coupled to the data TLB circuitry 872 in the memory unit circuitry 870. The instruction cache circuitry 834 is further coupled to the level 2 (L2) cache circuitry 876 in the memory unit circuitry 870. In one example, the instruction cache 834 and the data cache 874 are combined into a single instruction and data cache (not shown) in L2 cache circuitry 876, a level 3 (L3) cache circuitry (not shown), and/or main memory. The L2 cache circuitry 876 is coupled to one or more other levels of cache and eventually to a main memory.

The core 890 may support one or more instructions sets (e.g., the x86 instruction set architecture (optionally with some extensions that have been added with newer versions); the MIPS instruction set architecture; the ARM instruction set architecture (optionally with optional additional extensions such as NEON)), including the instruction(s) described herein. In one example, the core 890 includes logic to support a packed data instruction set architecture extension (e.g., AVX1, AVX2), thereby allowing the operations used by many multimedia applications to be performed using packed data.

The description herein includes numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Techniques and architectures for managing power consumption of a system are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

In one or more first embodiments, a circuit device comprises a hardware interface to couple the circuit device to a random access memory (RAM) device, a detector circuit coupled to the hardware interface, the detector circuit to detect a first difference between a threshold maximum refresh rate and a first refresh rate requested with the RAM device, an evaluation circuit coupled to the detector circuit, wherein while the RAM device is refreshed at the first refresh rate, the evaluation circuit is to perform a first identification of a first throttle action based on the difference, a control circuit coupled to the evaluation circuit, wherein based on the first identification, the control circuit is to generate one or more first control signals to throttle an operation of circuitry which is thermally coupled with the RAM device.

In one or more second embodiments, further to the first embodiment, the RAM device is to continue to be refreshed at the first refresh rate after the operation is throttled based on the one or more first control signals.

In one or more third embodiments, further to the first embodiment or the second embodiment, the circuit device is to be coupled to the RAM device via a memory controller, the one or more first control signals are to facilitate dynamic voltage and frequency scaling of the memory controller.

In one or more fourth embodiments, further to any of the first through third embodiments, the control circuit is to generate one or more first control signals while one or more compute engines are each coupled to access to the RAM device, and the one or more first control signals are to facilitate dynamic voltage and frequency scaling of the one or more compute engines.

In one or more fifth embodiments, further to any of the first through fourth embodiments, the control circuit is to generate one or more first control signals while one or more compute engines are each coupled to access to the RAM device, and the one or more first control signals are to prevent an execution of a software process by the one or more compute engines.

In one or more sixth embodiments, further to any of the first through fifth embodiments, the detector circuit is further to detect a second difference between the threshold maximum refresh rate and a second refresh rate requested with the RAM device, while the RAM device is refreshed at the second refresh rate, the evaluation circuit is further to perform a second identification of a power state based on the difference, based on the second identification, the control circuit is to generate one or more second control signals to mitigate a throttle of the operation.

In one or more seventh embodiments, further to the sixth embodiment, the RAM device is to continue to be refreshed at the second refresh rate after the throttle is mitigated based on the one or more second control signals.

In one or more eighth embodiments, further to any of the first through sixth embodiments, the detector circuit to detect a first difference comprises the detector circuit to determine that the first refresh rate is greater than the threshold maximum refresh rate.

In one or more ninth embodiments, further to any of the first through sixth embodiments, the evaluation circuit to perform the first identification of the first throttle action comprises the evaluation circuit to perform a search of reference information, based on the difference, to identify a power state, the reference information identifies multiple refresh states as corresponding each to a different respective power state of multiple power states, and the multiple refresh states each comprise a respective difference between the threshold maximum refresh rate and a different respective refresh rate.

In one or more tenth embodiments, one or more non-transitory computer-readable storage media have stored thereon instructions which, when executed by one or more processing units, cause the one or more processing units to perform a method comprising receiving a first identifier of a threshold maximum refresh rate, receiving a second identifier of a first refresh rate requested with a random access memory (RAM) device, while the RAM device is refreshed at the first refresh rate, performing a first evaluation based on both the first identifier and the second identifier, performing a first identification of a first throttling action based on the first evaluation, and based on the first identification, generating one or more first control signals to throttle an operation of circuitry which is thermally coupled with the RAM device.

In one or more eleventh embodiments, further to the tenth embodiment, the RAM device continues to be refreshed at the first refresh rate after the operation is throttled based on the one or more first control signals.

In one or more twelfth embodiments, further to the tenth embodiment or the eleventh embodiment, a memory controller is coupled to provide access to the RAM device, and the one or more first control signals are to facilitate dynamic voltage and frequency scaling of the memory controller.

In one or more thirteenth embodiments, further to any of the tenth through twelfth embodiments, one or more compute engines are each coupled to access to the RAM device, and the one or more first control signals are to facilitate dynamic voltage and frequency scaling of the one or more compute engines.

In one or more fourteenth embodiments, further to any of the tenth through thirteenth embodiments, one or more compute engines are each coupled to access to the RAM device, and the one or more first control signals are to prevent an execution of a software process by the one or more compute engines.

In one or more fifteenth embodiments, further to any of the tenth through fourteenth embodiments, the method further comprises receiving a third identifier of a second refresh rate requested with the RAM device, while the RAM device is refreshed at the second refresh rate, performing a second evaluation based on both the first identifier and the third identifier, based on the second evaluation, generating one or more second control signals to mitigate the first throttling action.

In one or more sixteenth embodiments, further to the fifteenth embodiment, the RAM device continues to be refreshed at the second refresh rate after the first throttling action based on the one or more second control signals.

In one or more seventeenth embodiments, further to any of the tenth through fifteenth embodiments, the first evaluation determines that the first refresh rate is greater than the threshold maximum refresh rate.

In one or more eighteenth embodiments, further to any of the tenth through fifteenth embodiments, performing the first evaluation comprises identifying a first difference between the threshold maximum refresh rate and the first refresh rate, performing the first identification of the first throttling action comprises performing a search of reference information, based on the difference, to identify a power state, the reference information identifies multiple refresh states as corresponding each to a different respective power state of multiple power states, and the multiple refresh states each comprise a respective difference between the threshold maximum refresh rate and a different respective refresh rate.

In one or more nineteenth embodiments, a system comprises a random access memory (RAM) device, one or more compute engines each to execute a respective set of instructions, a power management unit (PMU) coupled to the RAM device and the one or more compute engines, the PMU comprising a detector circuit to detect a first difference between a threshold maximum refresh rate and a first refresh rate requested with the RAM device, an evaluation circuit coupled to the detector circuit, wherein while the RAM device is refreshed at the first refresh rate, the evaluation circuit is to perform a first identification of a first throttle action based on the difference, and a control circuit coupled to the evaluation circuit, wherein based on the first identification, the control circuit is to generate one or more first control signals to throttle an operation of circuitry which is thermally coupled with the RAM device, and a network interface coupled to the one or more compute engines, the network interface to receive and transmit data over a network.

In one or more twentieth embodiments, further to the nineteenth embodiment, the RAM device is to continue to be refreshed at the first refresh rate after the operation is throttled based on the one or more first control signals.

In one or more twenty-first embodiments, further to the nineteenth embodiment or the twentieth embodiment, the system further comprises a memory controller coupled between the RAM device and the one or more compute engines, wherein the one or more first control signals are to facilitate dynamic voltage and frequency scaling of the memory controller.

In one or more twenty-second embodiments, further to any of the nineteenth through twenty-first embodiments, the one or more first control signals are to facilitate dynamic voltage and frequency scaling of the one or more compute engines.

In one or more twenty-third embodiments, further to any of the nineteenth through twenty-second embodiments, the one or more first control signals are to prevent an execution of a software process by the one or more compute engines.

In one or more twenty-fourth embodiments, further to any of the nineteenth through twenty-third embodiments, the detector circuit is further to detect a second difference between the threshold maximum refresh rate and a second refresh rate requested with the RAM device, while the RAM device is refreshed at the second refresh rate, the evaluation circuit is further to perform a second identification of a power state based on the difference, based on the second identification, the control circuit is to generate one or more second control signals to mitigate a throttle of the operation.

In one or more twenty-fifth embodiments, further to the twenty-fourth embodiment, the RAM device is to continue to be refreshed at the second refresh rate after the throttle is mitigated based on the one or more second control signals.

In one or more twenty-sixth embodiments, further to any of the nineteenth through twenty-fourth embodiments, the detector circuit to detect a first difference comprises the detector circuit to determine that the first refresh rate is greater than the threshold maximum refresh rate.

In one or more twenty-seventh embodiments, further to any of the nineteenth through twenty-fourth embodiments, the evaluation circuit to perform the first identification of the first throttle action comprises the evaluation circuit to perform a search of reference information, based on the difference, to identify a power state, the reference information identifies multiple refresh states as corresponding each to a different respective power state of multiple power states, and the multiple refresh states each comprise a respective difference between the threshold maximum refresh rate and a different respective refresh rate.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A circuit device comprising:
a hardware interface to couple the circuit device to a random access memory (RAM) device;
a detector circuit coupled to the hardware interface, the detector circuit to detect a first difference between a threshold maximum refresh rate and a first refresh rate requested with the RAM device;
an evaluation circuit coupled to the detector circuit, wherein while the RAM device is refreshed at the first refresh rate, the evaluation circuit is to perform a first identification of a first throttle action based on the difference;
a control circuit coupled to the evaluation circuit, wherein based on the first identification, the control circuit is to generate one or more first control signals to throttle an operation of circuitry which is thermally coupled with the RAM device.

2. The circuit device of claim 1, wherein the RAM device is to continue to be refreshed at the first refresh rate after the operation is throttled based on the one or more first control signals.

3. The circuit device of claim 1, wherein:
the circuit device is to be coupled to the RAM device via a memory controller;
the one or more first control signals are to facilitate dynamic voltage and frequency scaling of the memory controller.

4. The circuit device of claim 1, wherein:
the control circuit is to generate one or more first control signals while one or more compute engines are each coupled to access to the RAM device; and
the one or more first control signals are to facilitate dynamic voltage and frequency scaling of the one or more compute engines.

5. The circuit device of claim 1, wherein:
the control circuit is to generate one or more first control signals while one or more compute engines are each coupled to access to the RAM device; and
the one or more first control signals are to prevent an execution of a software process by the one or more compute engines.

6. The circuit device of claim 1, wherein:
the detector circuit is further to detect a second difference between the threshold maximum refresh rate and a second refresh rate requested with the RAM device;
while the RAM device is refreshed at the second refresh rate, the evaluation circuit is further to perform a second identification of a power state based on the difference;
based on the second identification, the control circuit is to generate one or more second control signals to mitigate a throttle of the operation.

7. The circuit device of claim 6, wherein the RAM device is to continue to be refreshed at the second refresh rate after the throttle is mitigated based on the one or more second control signals.

8. The circuit device of claim 1, wherein the detector circuit to detect a first difference comprises the detector circuit to determine that the first refresh rate is greater than the threshold maximum refresh rate.

9. The circuit device of claim 1, wherein:
the evaluation circuit to perform the first identification of the first throttle action comprises the evaluation circuit to perform a search of reference information, based on the difference, to identify a power state;
the reference information identifies multiple refresh states as corresponding each to a different respective power state of multiple power states; and
the multiple refresh states each comprise a respective difference between the threshold maximum refresh rate and a different respective refresh rate.

10. One or more non-transitory computer-readable storage media having stored thereon instructions which, when executed by one or more processing units, cause the one or more processing units to perform a method comprising:
receiving a first identifier of a threshold maximum refresh rate;
receiving a second identifier of a first refresh rate requested with a random access memory (RAM) device;
while the RAM device is refreshed at the first refresh rate, performing a first evaluation based on both the first identifier and the second identifier;
performing a first identification of a first throttling action based on the first evaluation; and
based on the first identification, generating one or more first control signals to throttle an operation of circuitry which is thermally coupled with the RAM device.

11. The one or more computer-readable storage media of claim 10, wherein the RAM device continues to be refreshed at the first refresh rate after the operation is throttled based on the one or more first control signals.

12. The one or more computer-readable storage media of claim 10, wherein:
one or more compute engines are each coupled to access to the RAM device; and
the one or more first control signals are to facilitate dynamic voltage and frequency scaling of the one or more compute engines.

13. The one or more computer-readable storage media of claim 10, the method further comprising:
receiving a third identifier of a second refresh rate requested with the RAM device;
while the RAM device is refreshed at the second refresh rate, performing a second evaluation based on both the first identifier and the third identifier;
based on the second evaluation, generating one or more second control signals to mitigate the first throttling action.

14. The one or more computer-readable storage media of claim 10, wherein the first evaluation determines that the first refresh rate is greater than the threshold maximum refresh rate.

15. The one or more computer-readable storage media of claim 10, wherein:
performing the first evaluation comprises identifying a first difference between the threshold maximum refresh rate and the first refresh rate;
performing the first identification of the first throttling action comprises performing a search of reference information, based on the difference, to identify a power state;
the reference information identifies multiple refresh states as corresponding each to a different respective power state of multiple power states; and
the multiple refresh states each comprise a respective difference between the threshold maximum refresh rate and a different respective refresh rate.

16. A system comprising:
a random access memory (RAM) device;
one or more compute engines each to execute a respective set of instructions;
a power management unit (PMU) coupled to the RAM device and the one or more compute engines, the PMU comprising:
a detector circuit to detect a first difference between a threshold maximum refresh rate and a first refresh rate requested with the RAM device;
an evaluation circuit coupled to the detector circuit, wherein while the RAM device is refreshed at the first refresh rate, the evaluation circuit is to perform a first identification of a first throttle action based on the difference; and
a control circuit coupled to the evaluation circuit, wherein based on the first identification, the control circuit is to generate one or more first control signals to throttle an operation of circuitry which is thermally coupled with the RAM device; and
a network interface coupled to the one or more compute engines, the network interface to receive and transmit data over a network.

17. The system of claim 16, wherein the RAM device is to continue to be refreshed at the first refresh rate after the operation is throttled based on the one or more first control signals.

18. The system of claim 16, wherein:
the detector circuit is further to detect a second difference between the threshold maximum refresh rate and a second refresh rate requested with the RAM device;
while the RAM device is refreshed at the second refresh rate, the evaluation circuit is further to perform a second identification of a power state based on the difference;
based on the second identification, the control circuit is to generate one or more second control signals to mitigate a throttle of the operation.

19. The system of claim 16, wherein the detector circuit to detect a first difference comprises the detector circuit to determine that the first refresh rate is greater than the threshold maximum refresh rate.

20. The system of claim 16, wherein:
the evaluation circuit to perform the first identification of the first throttle action comprises the evaluation circuit to perform a search of reference information, based on the difference, to identify a power state;
the reference information identifies multiple refresh states as corresponding each to a different respective power state of multiple power states; and
the multiple refresh states each comprise a respective difference between the threshold maximum refresh rate and a different respective refresh rate.
